(19) United States
(12) Patent Application Publication
(10) Pub. No.: US 2026/0086177 A1
(43) Pub. Date: Mar. 26, 2026

(54) RADIO-FREQUENCY AMPLIFYING APPARATUS AND MAGNETIC RESONANCE IMAGING APPARATUS

(71) Applicant: CANON MEDICAL SYSTEMS CORPORATION, Otawara-shi (JP)

(72) Inventors: Hirofumi YAMAKI, Nasushiobara (JP); Mitsuyuki MURAKAMI, Nasushiobara (JP); Aoi SAKAMITSU, Utsunomiya (JP); Masahiko ONO, Nasushiobara (JP)

(73) Assignee: CANON MEDICAL SYSTEMS CORPORATION, Otawara-shi (JP)

(21) Appl. No.: 19/302,148

(22) Filed: Aug. 18, 2025

(30) Foreign Application Priority Data
Sep. 25, 2024 (JP) 2024-166217

(51) Int. Cl. G01R 33/36; H03F 3/24; H03F 3/26

(52) U.S. Cl. CPC G01R 33/3614; H03F 3/245; H03F 3/265; H03F 2200/451

(57) ABSTRACT

A radio-frequency amplifying apparatus according to an exemplary embodiment includes an amplifier and control circuitry. The amplifier includes an amplifying element that amplifies a radio-frequency input signal, and a neutralizing capacitor that neutralizes feedback capacitance of the amplifying element. The control circuitry changes a drain voltage applied to the amplifying element according to a magnitude of the radio-frequency input signal and also applies the drain voltage to the neutralizing capacitor. The amplifier changes capacitance of the neutralizing capacitor according to a magnitude of the drain voltage.

### CROSS-REFERENCE TO RELATED APPLICATIONS

This application is based upon and claims the benefit of priority from Japanese Patent Application No. 2024-166217, filed September 25, 2024, the entire contents of which are incorporated herein by reference.

### FIELD

Embodiments described herein relate generally to a radio-frequency amplifying apparatus and a magnetic resonance imaging (MRI) apparatus.

### BACKGROUND

The MRI apparatus is an imaging apparatus that excites a nuclear spin of a subject placed in a static magnetic field with radio-frequency (RF) pulses at a Larmor frequency, that executes a scan to collect magnetic resonance (MR) signals generated from the subject due to the excitation, and that generates an MR image based on the MR signals collected by the scan.

In a radio-frequency amplifying apparatus (i.e., an RF amplifier) in the MRI apparatus, there is a case where a field effect transistor (FET) is used as an amplifying element of an amplifier. In such a case, circuitry is adjusted such that power efficiency becomes high near a rated output power. However, in a case where the magnitude of an output signal is significantly lower than a rated output, a drain voltage applied to the FET becomes excessive, and power efficiency of the RF amplifier is reduced. In a pulse sequence in which RF pulses with relatively long application times are applied, a load put on the RF amplifier is large, and thus high power efficiency is desired.

Hence, to prevent the power efficiency from decreasing even in a case where the magnitude of the output signal is significantly lower than the rated output, a circuit configuration is known in which the drain voltage applied to the FET is changed according to the amount of output power. Further, the RF amplifier is generally designed so that an oscillation phenomenon does not occur.

### BRIEF DESCRIPTION OF THE DRAWINGS

FIG. 1 is a block diagram illustrating an example of an overall configuration of a magnetic resonance imaging (MRI) apparatus according to exemplary embodiments;

FIG. 2 is a block diagram illustrating an example of a configuration of a radio-frequency (RF) transmitter according to a first exemplary embodiment and a second exemplary embodiment;

FIG. 3 is a schematic circuitry diagram illustrating an example of an amplifier according to a comparative example;

FIG. 4 is a graph illustrating a relationship between feedback capacitance of a field effect transistor (FET) and a drain voltage;

FIG. 5 is a schematic circuitry diagram illustrating an example of an amplifier according to the first exemplary embodiment;

FIG. 6 is a graph illustrating a relationship between capacitance of a neutralizing capacitor and a reverse voltage according to the exemplary embodiments;

FIG. 7 is a flowchart illustrating an example of an operation of an RF amplifier according to the first exemplary embodiment;

FIG. 8 is a schematic circuitry diagram illustrating an example of an amplifier according to the second exemplary embodiment;

FIG. 9 is a block diagram illustrating an example of a configuration of an RF transmitter according to a third exemplary embodiment; and

FIG. 10 is a schematic circuitry diagram illustrating an example of an amplifier according to the third exemplary embodiment;

### DETAILED DESCRIPTION

A radio-frequency amplifying apparatus according to an exemplary embodiment includes an amplifier and control circuitry. The amplifier includes an amplifying element that amplifies a radio-frequency input signal, and a neutralizing capacitor that neutralizes feedback capacitance of the amplifying element. The control circuitry changes a drain voltage applied to the amplifying element according to a magnitude of the radio-frequency input signal and also applies the drain voltage to the neutralizing capacitor. The amplifier changes capacitance of the neutralizing capacitor according to a magnitude of the drain voltage.

Various Embodiments will be described hereinafter with reference to the accompanying drawings.

In each drawing, identical elements are denoted by the same reference numerals, and redundant descriptions thereof are omitted.

### (Overall Configuration of MRI Apparatus)

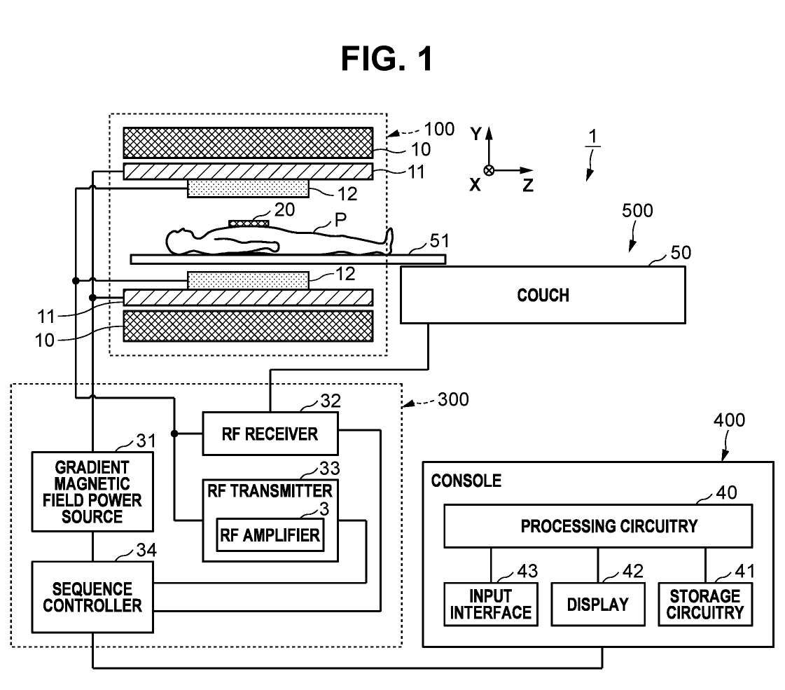

FIG. 1 is a block diagram illustrating an example of an overall configuration of a magnetic resonance imaging (MRI) apparatus 1 according to exemplary embodiments. The MRI apparatus 1 includes a gantry 100, a control cabinet 300, a console 400, and a couch 500.

The gantry 100 includes a static magnetic field magnet 10, a gradient magnetic field coil 11, and a whole body (WB) coil 12. These constituent elements are accommodated in a cylindrical chassis.

The static magnetic field magnet 10 has a substantially cylindrical shape, and generates a static magnetic field in a bore into which a patient to be a subject is carried. The bore mentioned herein refers to an examination space inside a cylinder of the static magnetic field magnet 10. A superconductive coil is built into the static magnetic field magnet 10 and is cooled by liquid helium to an extremely low temperature. The static magnetic field magnet 10 generates a static magnetic field by applying a current supplied from a static magnetic field power source (not illustrated) to the superconductive coil in an excitation mode. Then, when the static magnetic field magnet 10 transitions to a persistent current mode, the static magnetic field power source is disconnected. Once the static magnetic field magnet 10 transitions to the persistent current mode, the static magnetic field magnet 10 keeps generating a large static magnetic field for a long period of time, for example, more than a year. The static magnetic field magnet 10 may be constituted of, for example, a permanent magnet.

The gradient magnetic field coil 11 has a substantially cylindrical shape, and is fixed to the inside of the static magnetic field magnet 10 in a radial direction of the cylindrical shape. The gradient magnetic field coil 11 is supplied with a current from a gradient magnetic field power source 31 and generates a gradient magnetic field. The gradient magnetic field coil 11 is formed of a combination of three coils respectively corresponding to an X-axis, a Y-axis, and a Z-axis, which are orthogonal to one another. The three coils are individually supplied with currents from the gradient magnetic field power source 31, and generate gradient magnetic fields in which magnetic field intensities change along the X-axis, the Y-axis, and the Z-axis, respectively.

As illustrated in FIG. 1, a left-right direction of a subject P placed on the couch 500 is an X-axis direction, a front-back direction (body thickness direction) thereof is a Y-axis direction, and a head-feet direction thereof is a Z-axis direction. The X-axis, the Y-axis, and the Z-axis are orthogonal to one another.

The WB coil 12 has a substantially cylindrical shape and is an RF coil that is fixed to the inside of the gradient magnetic field coil 11 so as to surround the subject P. The WB coil 12 transmits an RF pulse transmitted from an RF transmitter 33 to the subject P, and receives a magnetic resonance (MR) signal emitted from the subject P due to excitation of hydrogen nuclei.

The MRI apparatus 1 may include, in addition to the WB coil 12, a local coil 20. The local coil 20 is an RF coil disposed in proximity to the subject P, and receives the MR signal emitted from the subject P at a position close to the subject P. The local coil 20 may transmit an RF pulse transmitted from the RF transmitter 33 to the subject P. There are various types of the local coil 20 corresponding to imaging regions of the subject, such as a head region, a chest region (for example, see FIG. 1), a spine, a lower extremity, and the whole body.

The control cabinet 300 includes the gradient magnetic field power source 31, an RF receiver 32, the RF transmitter 33, and a sequence controller 34. Under control of the sequence controller 34, the gradient magnetic field power source 31 supplies currents to the gradient magnetic field coil 11, and causes the gradient magnetic field coil 11 to generate the gradient magnetic fields along the X-axis, the Y-axis, and the Z-axis.

Based on an instruction from the sequence controller 34, the RF transmitter 33 generates an RF pulse train in a Larmor frequency band as an RF transmission wave, outputs the RF pulse train to the RF coil, and excites the subject P. Details of the RF transmitter 33 will be described below.

The RF receiver 32 performs analog to digital (AD) conversion on the MR signal received by the RF coil and outputs the MR signal to the sequence controller 34. The digitized MR signal is referred to as raw data.

Under control of the console 400, the sequence controller 34 drives the gradient magnetic field power source 31, the RF transmitter 33, and the RF receiver 32 individually to execute a scan of the subject P. The sequence controller 34 receives raw data from the RF receiver 32 by executing the scan, and transmits the raw data to the console 400.

The sequence controller 34 includes processing circuitry (not illustrated). The processing circuitry of the sequence controller 34 is composed of, for example, a processor that executes a predetermined program, and hardware such as a field-programmable gate array (FPGA) or an application-specific integrated circuit (ASIC).

The couch 500 includes a couch main body 50 and a couchtop 51. The couch main body 50 is capable of moving the couchtop 51 in a vertical direction and a horizontal direction, and moves up the subject P placed on the couchtop 51 to a predetermined height and to the inside of the bore.

The console 400 includes processing circuitry 40, storage circuitry 41, a display 42, and an input interface 43. The console 400 is an example of an image processing apparatus configured using a computer.

The storage circuitry 41 is a storage medium including an external storage device such as a hard disk drive (HDD) or an optical disk device, in addition to a read only memory (ROM) and a random access memory (RAM). The storage circuitry 41 stores various kinds of information and data, and stores various kinds of programs executed by a processor included in the processing circuitry 40.

A display 42 is a display device such as a liquid crystal display panel, a plasma display panel, or an organic electroluminescent (EL) panel. The display 42 may be a graphic user interface (GUI) that displays, under control of the processing circuitry 40, various kinds of information and data and also functions as an input device.

The input interface 43 includes various input devices for a user to input various kinds of information and data, and input circuitry that processes a signal from each of the input devices. Each input device may be, for example, a mouse, a keyboard, a trackball, or a touch panel. When the input device is operated, the input circuitry generates a signal corresponding to the operation and outputs the signal to the processing circuitry 40.

The processing circuitry 40 is, for example, a central processing unit (CPU) or circuitry including a dedicated or general-purpose processor. The processor executes various kinds of programs stored in advance in the storage circuitry 41 or directly incorporated into the processing circuitry 40.

With these constituent elements, the console 400 controls the entire MRI apparatus 1. Specifically, the processing circuitry 40 accepts an instruction regarding an imaging condition or other information of various kinds in response to an operation performed by the user, such as a laboratory technician, via the input interface 43. The processing circuitry 40 then causes the sequence controller 34 to execute a scan based on the input imaging condition. Further, the processing circuitry 40 re-constructs an MR image based on the raw data transmitted from the sequence controller 34. The re-constructed MR image is displayed on the display 42 and stored in the storage circuitry 41.

### RF transmitter

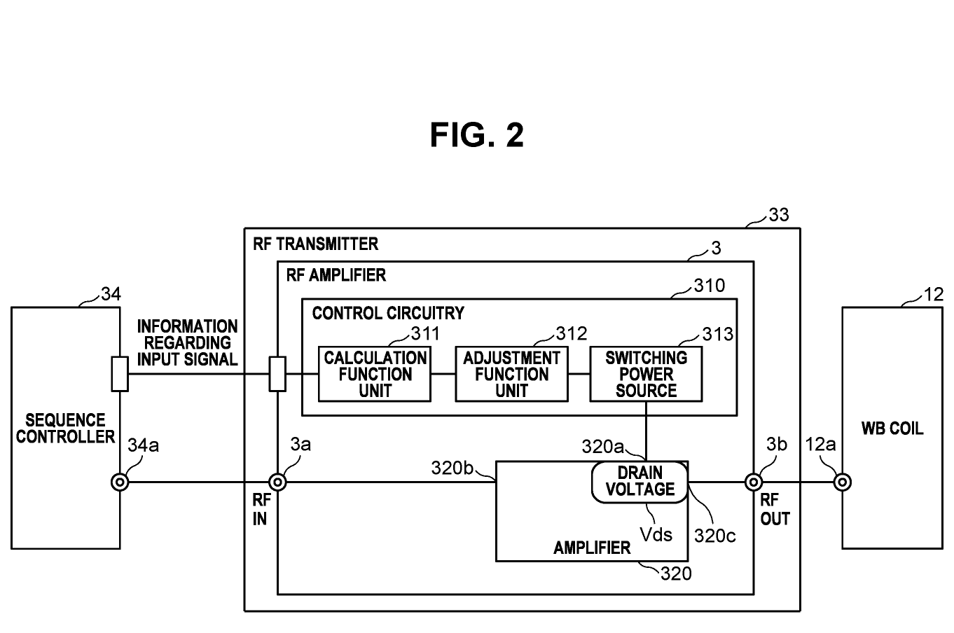

FIG. 2 is a block diagram illustrating an example of a configuration of the RF transmitter 33 according to a first exemplary embodiment and a second exemplary embodiment. The RF transmitter 33 includes a radio-frequency amplifying apparatus (i.e., an RF amplifier) 3. Based on an instruction from the sequence controller 34, the RF transmitter 33 generates an RF pulse train in a Larmor frequency band as an RF transmission wave, outputs the RF pulse train to the RF coil, and excites the subject P. The RF coil from which the RF transmission wave is output may be the WB coil 12 or the local coil 20.

Specifically, an output terminal 34a of the sequence controller 34 and an input terminal 3a of the RF amplifier 3 are connected to each other, and the RF amplifier 3 inputs an RF pulse (i.e., a radio-frequency input signal) output from the sequence controller 34 via the input terminal 3a. Further, the RF amplifier 3 acquires information regarding the input signal from the sequence controller 34.

The information regarding the input signal mentioned herein is information including information regarding a timing to apply the RF pulse and a waveform, and is, for example, information including a peak value of the RF pulse that is applied at each time point. The information regarding the input signal may include information regarding the RF pulse such as a pulse width, information regarding a sequence name of a pulse sequence to be executed, and information regarding whether the pulse sequence is to be executed as a preliminary pre-scan or as a main scan to obtain a diagnosis image.

The RF amplifier 3 includes control circuitry 310 and an amplifier 320. One amplifier 320 or a plurality of amplifiers 320 may be included in the RF amplifier 3. In the RF amplifier 3, the plurality of amplifiers 320 is connected in parallel, so that a radio-frequency input signal can be output as a desired high power to the RF coil.

The control circuitry 310 includes various kinds of electronic circuitry, a processor, and the like. The control circuitry 310 is provided with a calculation function unit 311, an adjustment function unit 312, and a switching power source 313. Details of the calculation function unit 311, the adjustment function unit 312, and the switching power source 313 will be described below.

The amplifier 320 includes an amplifying element that amplifies a radio-frequency input signal. The amplifying element in the amplifier 320 is configured, for example, using a field effect transistor (FET). Under control of the control circuitry 310, the amplifier 320 amplifies the input signal input to an input terminal 320b in a state where a predetermined drain voltage Vds is applied to a power source terminal 320a connected to a drain D of the FET in the amplifier 320, and outputs an amplified signal to the RF coil via an output terminal 320c. The RF coil may be the WB coil 12 or the local coil 20.

In a case where the FET is used as the amplifying element of the amplifier 320, peripheral circuitry of the FET is adjusted so that power efficiency is high in a state where an output signal is approximately the rated output. The approximately constant drain voltage Vds is normally applied to the power source terminal 320a of the amplifier 320 regardless of the magnitude (i.e., the peak value) of the input signal input to the input terminal 320b. However, in a case where the magnitude of the output signal is significantly lower than the rated output, the drain voltage Vds applied becomes excessive compared to a drain voltage appropriate for the magnitude of the input signal, which causes a phenomenon leading to a decrease in power efficiency of the RF amplifier 3.

To avoid such a decrease in power efficiency, the control circuitry 310 changes the drain voltage Vds applied to the power source terminal 320a so as not to become excessive compared to the drain voltage appropriate for the magnitude of the input signal input to the input terminal 320b. In other words, the control circuitry 310 changes the drain voltage Vds applied to the amplifying element according to the magnitude of the input signal input to the input terminal 320b. The control circuitry 310 dynamically changes the drain voltage Vds according to the magnitude of the input signal during execution of a pulse sequence, and can thereby avoid the decrease in power efficiency and achieve a reduction of power consumption.

Furthermore, in a pulse sequence at a high duty ratio in which RF pulses, each with a relatively long application time, are applied, a load put on the RF amplifier 3 is large, and thus high power efficiency is desired. The high power efficiency suppresses heat generation of the RF amplifier itself. Hence, a circuit configuration is known in which the drain voltage Vds applied to the FET according to the magnitude of the output signal is changed to prevent the power efficiency from decreasing even in a case where the magnitude of the output signal is significantly lower than the rated output.

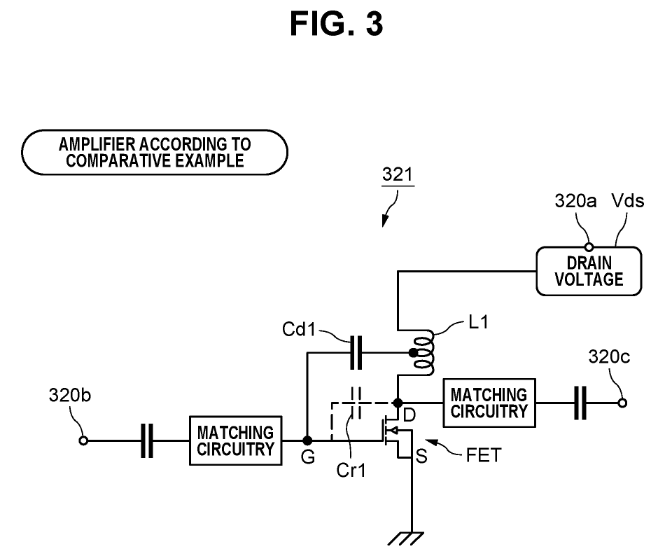

In an amplifier that uses an FET as an amplifying element, there is a case where an operation of the amplifier becomes unstable and oscillation occurs due to occurrence of positive feedback from an output side to an input side by a feedback capacitor as an intrinsic parasitic capacitor in the FET (i.e., a feedback capacitor in the FET). It is known that such an oscillation phenomenon is likely to occur particularly at the time of a load mismatch. FIG. 3 is a schematic circuitry diagram illustrating an example of a conventional amplifier 321 according to a comparative example.

The amplifier 321 according to the comparative example includes at least an FET as an amplifying element and a fixed capacitance capacitor Cd1 as a neutralizing capacitor. Under control of the control circuitry 310, the predetermined drain voltage Vds is applied to a drain D of the FET from the power source terminal 320a of the amplifier via an inductor L1. An input signal is input from the input terminal 320b to a gate G of the FET via a capacitor and matching circuitry on the input side. An amplified signal amplified by the FET is then output from the drain D of the FET to the output terminal 320c via matching circuitry and a capacitor on the output side.

One end of the fixed capacitance capacitor Cd1 is connected to a midpoint of the inductor L1, and the other end of the fixed capacitance capacitor Cd1 is connected to the gate G of the FET. With this configuration, a reverse voltage that is opposite to the drain voltage Vds applied to the FET is applied to the fixed capacitance capacitor Cd1, and a direction of a current flowing in the fixed capacitance capacitor Cd1 and a direction of a current flowing in a feedback capacitor Cr1 in the FET become opposite to each other. As a result, a feedback capacitance of the feedback capacitor Cr1 is canceled out by the capacitance of the fixed capacitance capacitor Cd1. In other words, the feedback capacitance of the feedback capacitor Cr1 is neutralized by the fixed capacitance capacitor Cd1 as the neutralizing capacitor.

As described above, in the conventional amplifier 321 according to the comparative example, the neutralizing capacitor is configured by using the fixed capacitance capacitor Cd1. In other words, the neutralizing capacitor in the conventional amplifier 321 is designed so that the feedback capacitance of the FET is constant.

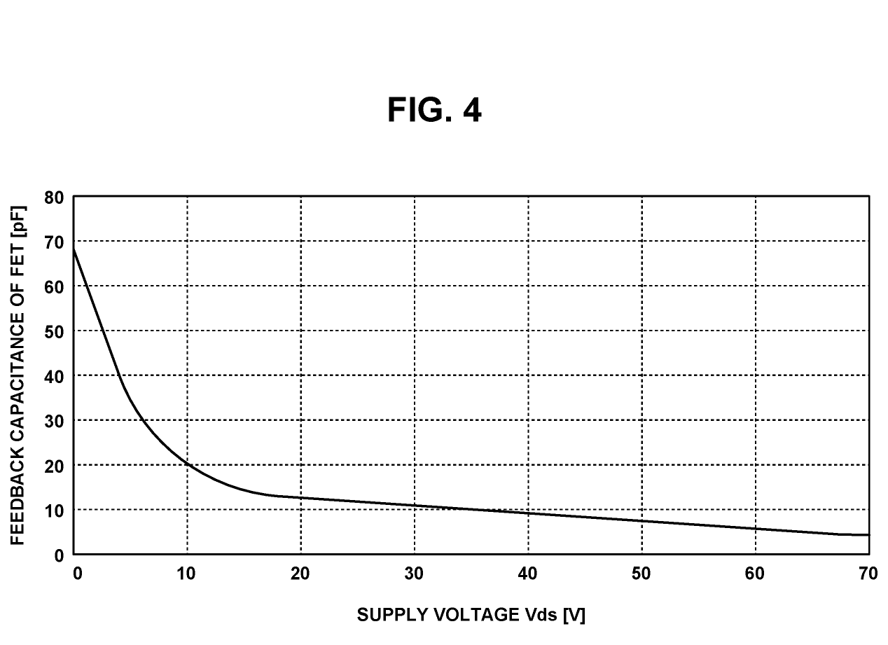

It is known that, however, the feedback capacitance of the FET being constant is limited to when the drain voltage Vds applied to the FET is constant, and the feedback capacitance also changes when the drain voltage Vds applied to the FET changes. FIG. 4 is a graph illustrating a relationship between the feedback capacitance of the FET and the drain voltage Vds. As illustrated in FIG. 4, the feedback capacitance of the FET changes according to the magnitude of the drain voltage Vds (i.e., a supply voltage) applied to the FET. Specifically, the higher the drain voltage Vds applied to the FET is, the smaller the feedback capacitance of the FET becomes.

In contrast, in the circuit configuration in which the drain voltage Vds applied to the FET is changed according to the magnitude of the output signal illustrated in FIG. 2, the drain voltage Vds is changed so as not to become excessive compared to the drain voltage that is appropriate for the magnitude of the input signal to avoid a decrease in power efficiency. Since the feedback capacitance of the FET changes with the change of the drain voltage Vds, in the circuit configuration of using the conventional fixed capacitance capacitor Cd1 as the neutralizing capacitor, there is a case where the neutralizing capacitor cannot sufficiently neutralize the feedback capacitance of the FET (i.e., the neutralizing capacitor does not function as neutralizing circuitry), and thus it is not possible to appropriately suppress the oscillation phenomenon that occurs at the time of a load mismatch.

To address this, the amplifier 320 according to the exemplary embodiments employs a means of changing the capacitance of the neutralizing capacitor according to the drain voltage Vds applied to the FET, which enables the neutralizing capacitor to function as the neutralizing circuitry even in a case where the feedback capacitance of the FET changes.

### First Exemplary Embodiment

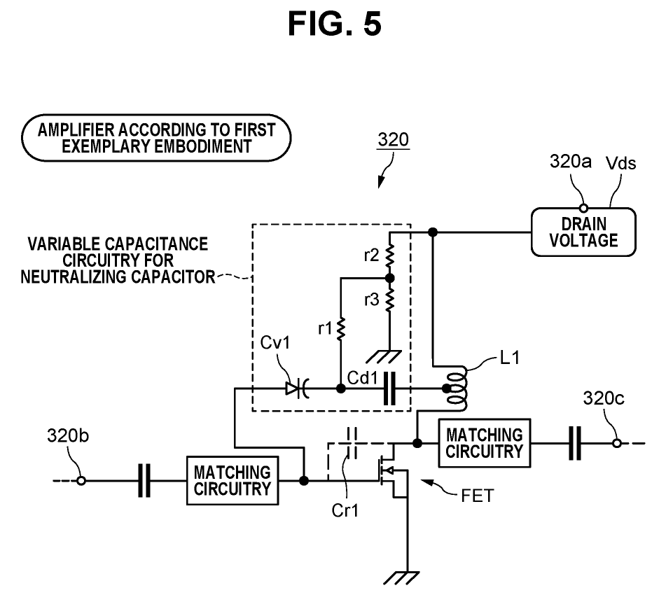

FIG. 5 is a schematic circuitry diagram illustrating an example of the amplifier 320 according to the first exemplary embodiment. The amplifier 320 is different from the amplifier 321 according to the comparative example in that the amplifier 320 includes variable capacitance circuitry for the neutralizing capacitor as a means of changing the capacitance of the neutralizing capacitor according to the magnitude of the drain voltage Vds applied to the FET. A circuitry configuration that is substantially the same as that of the amplifier 321 according to the comparative example is denoted by the same reference numerals, and a description that overlaps with the description regarding FIG. 3 is omitted.

The amplifier 320 includes the amplifying element that amplifies a radio-frequency input signal, and the neutralizing capacitor for neutralizing the feedback capacitance of the amplifying element. The neutralizing capacitor of the amplifier 320 includes the fixed capacitance capacitor Cd1 and a variable capacitance diode (i.e., varicap diode) Cv1.

The control circuitry 310 applies the drain voltage Vds to the variable capacitance diode Cv1. The amplifier 320 divides the drain voltage Vds and applies the divided drain voltage Vds to the variable capacitance diode Cv1. In FIG. 5, the drain voltage Vds applied to the FET is divided by resistors r1, r2, and r3 and applied to the variable capacitance diode Cv1.

The amplifier 320 changes the capacitance of the neutralizing capacitor according to the magnitude of the drain voltage Vds. Specifically, when the magnitude of the drain voltage Vds applied to the FET changes, a voltage applied to the variable capacitance diode Cv1 changes, and the capacitance of the variable capacitance diode Cv1 changes. As the capacitance of the variable capacitance diode Cv1 changes, the capacitance of the neutralizing capacitor, which is a combined capacitance of the capacitance of the fixed capacitance capacitor Cd1 and the capacitance of the variable capacitance diode Cv1, changes.

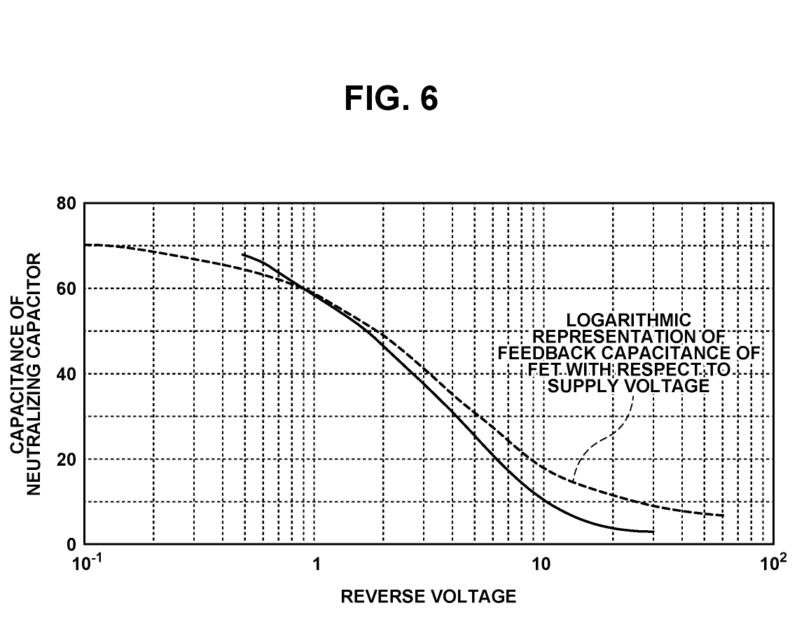

FIG. 6 is a graph illustrating a relationship between the capacitance of the neutralizing capacitor and a reverse voltage according to exemplary embodiments. Decreasing the reverse voltage applied to the variable capacitance diode Cv1 increases the capacitance of the variable capacitance diode Cv1, and also increases the capacitance of the neutralizing capacitor. Increasing the reverse voltage applied to the variable capacitance diode Cv1 decreases the capacitance of the variable capacitance diode Cv1, and also decreases the capacitance of the neutralizing capacitor.

A broken line in FIG. 6 logarithmically represents a relationship between the capacitance of the feedback capacitor Cr1 in the FET and the drain voltage Vds in FIG. 4. As illustrated in FIG. 6, the capacitance of the neutralizing capacitor and the capacitance of the feedback capacitor Cr1 according to the exemplary embodiments exhibit similar change tendencies that the capacitance decreases when the applied voltage is high and the capacitance increases when the applied voltage is lower. Employing circuitry that cancels out these change tendencies in the amplifier 320 according to the exemplary embodiments makes it possible for the neutralizing capacitor to neutralize the capacitance of the feedback capacitor Cr1 with high accuracy even in the case where the feedback capacitance of the FET changes.

A configuration of the neutralizing capacitor is not limited to the configuration including the variable capacitance diode Cv1, and may be a configuration including a plurality of fixed capacitance capacitors having different capacitances. In this case, the control circuitry 310 causes a selection means using switching or the like to select, from the plurality of fixed capacitance capacitors, a fixed capacitance capacitor with desired capacitance based on the magnitude of the drain voltage Vds, to thereby change the capacitance of the neutralizing capacitor according to the magnitude of the drain voltage Vds.

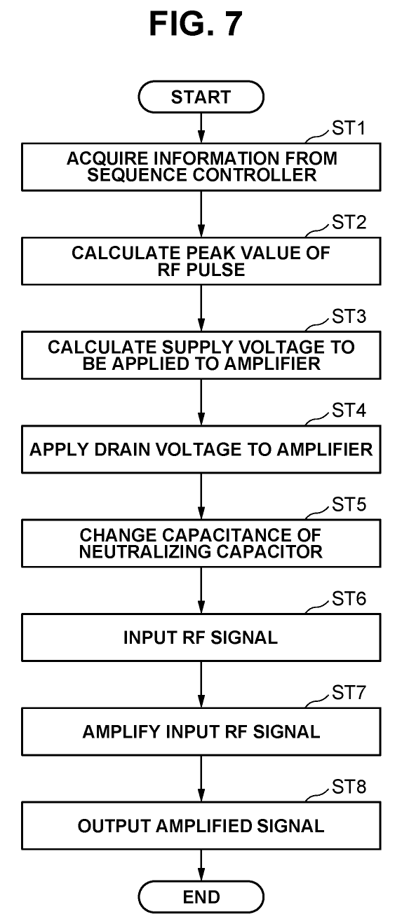

FIG. 7 is a flowchart illustrating an example of an operation of the RF amplifier 3 according to the first exemplary embodiment.

In step ST1, the calculation function unit 311 acquires information regarding an input signal output from the sequence controller 34. In other words, the sequence controller 34 outputs information regarding a radio-frequency input signal.

In step ST2, the calculation function unit 311 calculates a peak value of an RF pulse (or input power) input to the amplifier 320 based on the information regarding the input signal acquired from the sequence controller 34.

In step ST3, the calculation function unit 311 calculates the drain voltage Vds to be applied to the power source terminal 320a of the amplifier 320 based on the calculated peak value of the RF pulse. The magnitude of the supply voltage is calculated so that an output intensity of a signal output to the RF coil becomes a predetermined output intensity necessary for executing the pulse sequence and desired power efficiency is obtained.

To calculate the magnitude of the supply voltage to the power source terminal 320a of the amplifier 320, the calculation function unit 311 may use a relational expression between the peak value of the RF pulse and the supply voltage, or acquire and use a lookup table indicating a relationship between the peak value of the RF pulse and the supply voltage.

Further, the calculation function unit 311 may apply RF pulses to the subject to perform a pre-scan, and calculate the magnitude of the supply voltage to the power source terminal 320a of the amplifier 320 based on a condition determined from data obtained by the pre-scan. Furthermore, the calculation function unit 311 may take into account a type of pulse sequence to be executed or the like to calculate a value of the supply voltage to the power source terminal 320a of the amplifier 320.

In step ST4, the adjustment function unit 312 acquires, from the calculation function unit 311, information regarding the magnitude of the supply voltage to the power source terminal 320a of the amplifier 320. The adjustment function unit 312 then outputs, to the switching power source 313, a control signal for the switching power source 313 to supply the calculated drain voltage Vds to the power source terminal 320a of the amplifier 320.

The switching power source 313 applies the drain voltage Vds to the power source terminal 320a of the amplifier 320 based on the control signal output from the adjustment function unit 312.

In step ST5, under control of the adjustment function unit 312, the switching power source 313 applies the drain voltage Vds to the neutralizing capacitor. For example, the switching power source 313 applies the drain voltage Vds to the variable capacitance diode Cv1. The amplifier 320 divides the drain voltage Vds and applies the divided drain voltage Vds to the variable capacitance diode Cv1. For example, the drain voltage Vds applied to the FET and the neutralizing capacitor are coupled to each other via resistors, and the drain voltage Vds is divided.

In this manner, the control circuitry 310 acquires information regarding the input signal output from the sequence controller 34, and changes the drain voltage Vds based on the information regarding the input signal. Furthermore, the control circuitry 310 changes the drain voltage Vds applied to the amplifying element according to the magnitude of the input signal, and supplies the drain voltage Vds to the neutralizing capacitor.

In step ST6, the amplifier 320 accepts a radio-frequency input signal from the sequence controller 34 via the input terminal 320b. The input signal is input from the sequence controller 34 as analog data or digital data.

In step ST7, the amplifier 320 amplifies the input signal input to the input terminal 320b in a state where the drain voltage Vds, determined in step ST4, is applied to the power source terminal 320a. The radio-frequency input signal is amplified by the amplifying element of the amplifier 320.

In step ST8, the RF amplifier 3 outputs the amplified signal, amplified in step ST7, to the RF coil. The processing from steps ST4 to ST8 is an operation performed by analog circuitry and substantially performed at approximately the same time.

In this manner, the RF amplifier 3 and the MRI apparatus 1 according to the first exemplary embodiment include a means of changing the capacitance of the neutralizing capacitor according to the magnitude of the drain voltage Vds applied to the FET, whereby the neutralizing capacitor functions as the neutralizing circuitry even in the case where the feedback capacitance of the FET changes. This can further suppress oscillation even at the time of a load mismatch. In other words, the RF amplifier 3 and the MRI apparatus 1 according to the first exemplary embodiment make it possible to improve power efficiency while suppressing oscillation.

### (Second Exemplary Embodiment)

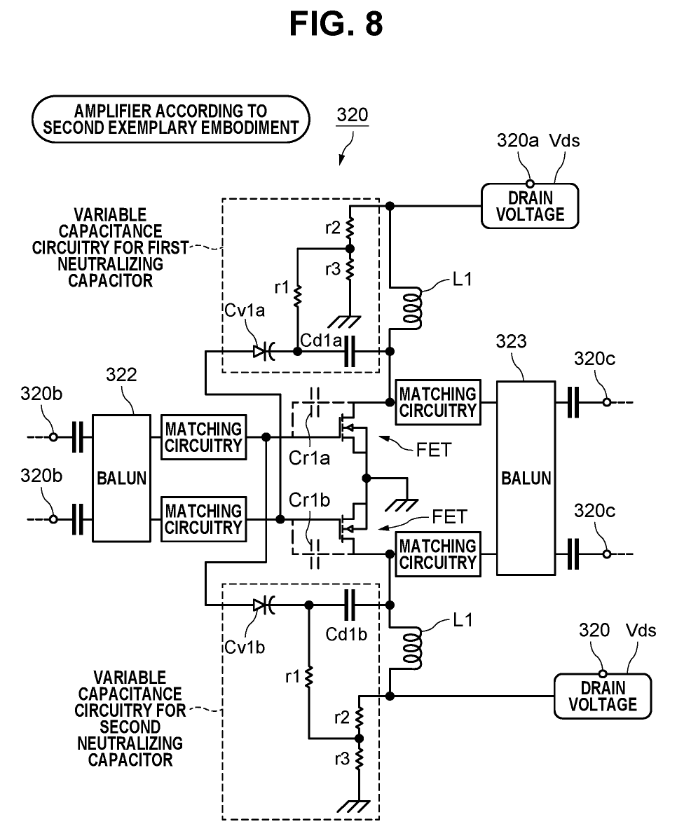

FIG. 8 is a schematic circuitry diagram illustrating an example of an amplifier 320 according to the second exemplary embodiment. The second exemplary embodiment is different from the first exemplary embodiment in that a circuit configuration of the amplifier 320 is push-pull circuitry.

The amplifier 320 according to the second exemplary embodiment is the push-pull circuitry including two neutralizing capacitors disposed between a first balun 322 and a second balun 323 that makes a 180-degree phase difference (i.e., reverse phases) between polarities of input signals. A circuitry configuration of variable capacitance circuitry for a first neutralizing capacitor, which includes a first variable capacitance diode Cv1a and a first fixed capacitance capacitor Cd1a, and a circuitry configuration of variable capacitance circuitry for a second neutralizing capacitor, which includes a second variable capacitance diode Cv1b and a second fixed capacitance capacitor Cd1b, are basically identical.

In the variable capacitance circuitry for the first neutralizing capacitor, the drain voltage Vds to be applied to a first FET is divided by resistors r1, r2, and r3 and applied to the first variable capacitance diode Cv1a. In the variable capacitance circuitry for the second neutralizing capacitor, the drain voltage Vds to be applied to a second FET is divided by the resistors r1, r2, and r3, and applied to the second variable capacitance diode Cv1b.

In the second exemplary embodiment, the two neutralizing capacitors are connected to respective ends of inductors L1 and L2, and with the first balun 322 interposed therebetween, a direction of a current flowing through the first neutralizing capacitor and a direction of a current flowing through the second neutralizing capacitor become opposite to each other. Hence, the current flowing through the second neutralizing capacitor is brought back to the first FET side on which a first feedback capacitor Cr1a is included to neutralize the capacitance of the first feedback capacitor Cr1a. Similarly, the current flowing through the first neutralizing capacitor is brought back to the second FET side on which a second feedback capacitor Cr1b is included to neutralize the capacitance of the second feedback capacitor Cr1b.

An amplified signal amplified by the first FET and an amplified signal amplified by the second FET are brought back into the same phase by passing through the second balun 323, combined with each other, and output to the output terminal 320c. With the RF amplifier 3 and the MRI apparatus 1 according to the second exemplary embodiment, amplification is achieved more efficiently while effects similar to those of the first exemplary embodiment are maintained.

### (Third Exemplary Embodiment)

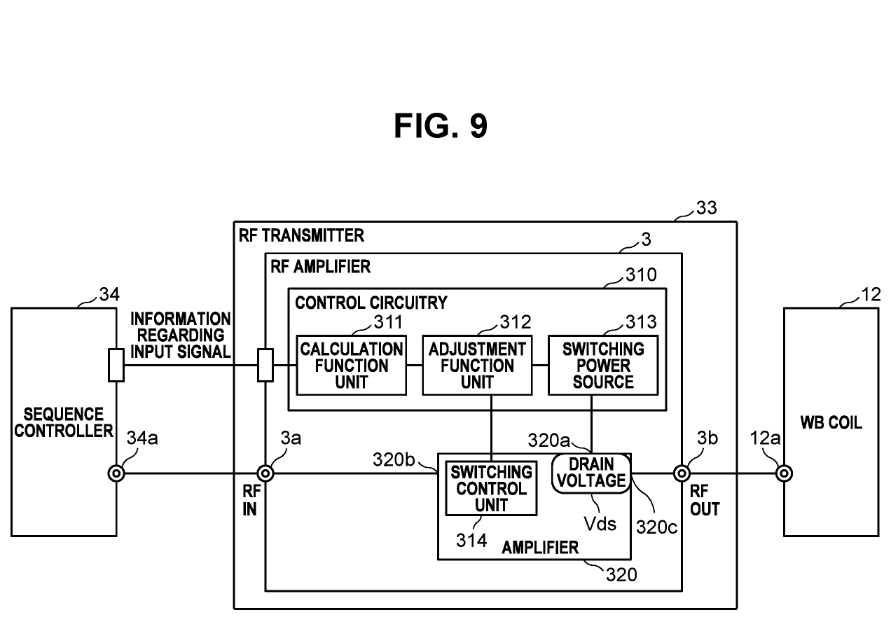

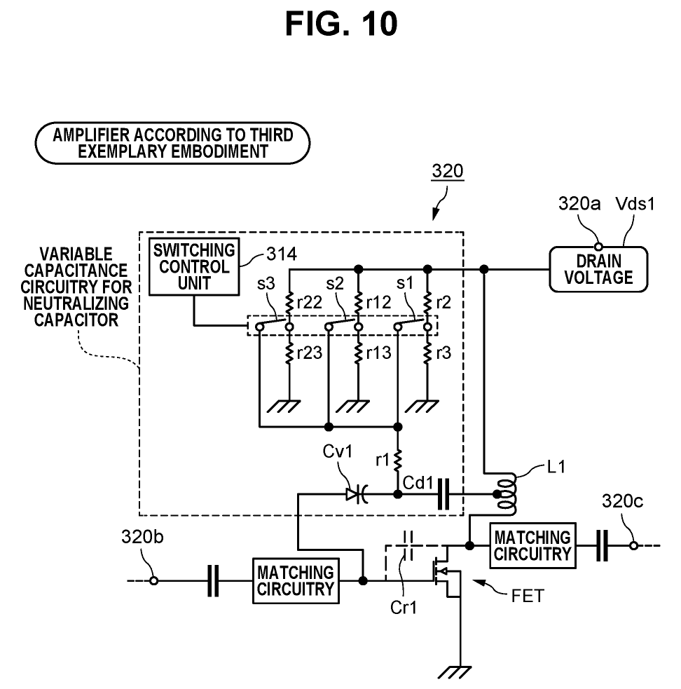

FIG. 9 is a block diagram illustrating an example of a configuration of an RF transmitter 33 according to a third exemplary embodiment. The third exemplary embodiment is different from the first exemplary embodiment in that the amplifier 320 includes a switching control unit 314, and the control circuitry 310 changes a voltage dividing ratio of a voltage to be applied to the variable capacitance diode Cv1 according to the magnitude of the drain voltage Vds. FIG. 10 is a schematic circuitry diagram illustrating an example of an RF amplifier 3 according to the third exemplary embodiment. In the first exemplary embodiment, the neutralizing capacitor includes the resistors r1, r2, and r3, and the voltage dividing ratio of the drain voltage Vds is determined by the resistors r1, r2, and r3. In contrast, in the third exemplary embodiment, the neutralizing capacitor includes a plurality of resistors r1, r2, r3, r11, r12, r13, r21, r22, and r23.

In the third exemplary embodiment, the adjustment function unit 312 in the control circuitry 310 further provides an instruction for the switching control unit 314 to switch between ON and OFF of switches s1, s2, and s3 based on information regarding the magnitude of a supply voltage to the power source terminal 320a of the amplifier 320. Following the instruction, the switching control unit 314 performs control to switch between ON and OFF so that at least one of the switches s1, s2, and s3 is turned ON, to perform switching of the plurality of resistors.

When the first switch s1 is turned ON by the switching control unit 314, the drain voltage Vds is divided via the resistors r2 and r3. When the second switch s2 is turned ON, the drain voltage Vds is divided via the resistors r12 and r13. When the third switch s3 is turned ON, the drain voltage Vds is divided via the resistors r22 and r23. The number of resistors to be switched by the switches is not limited to three as illustrated in FIG. 10, and may be two or more. In this manner, the control circuitry 310 controls the switches to switch the plurality of resistors to change the voltage dividing ratio of the drain voltage.

As indicated by the solid line and the broken line in FIG. 6, even in a case where the capacitance of the feedback capacitor Cr1 in the FET and the capacitance of the neutralizing capacitor are different from each other with respect to the same voltage, by adjusting the voltage dividing ratio of the voltage applied to the variable capacitance diode Cv1, it is possible to make the capacitance of the feedback capacitor Cr1 and the capacitance of the neutralizing capacitor approximately equal.

Additionally, as indicated by the solid line and the broken line in FIG. 6, even in a case where the capacitance of the neutralizing capacitor exhibits a non-linear characteristic with respect to the reverse voltage, by selecting a desired voltage dividing ratio from a plurality of voltage dividing ratio, it is possible to increase a degree of matching between the capacitance of the feedback capacitor Cr1 and the capacitance of the neutralizing capacitor. In other words, with the RF amplifier 3 and the MRI apparatus 1 according to the third exemplary embodiment, it is possible to implement the neutralizing capacitor that follows the change in the feedback capacitance of the FET with higher accuracy than that in the first exemplary embodiment.

With the RF amplifying apparatus and the MRI apparatus according to at least one of the above-described exemplary embodiments, it is possible to improve power efficiency while suppressing oscillation of the RF amplifying apparatus.

In the above exemplary embodiments, the term "processor" means circuitry such as a dedicated or general-purpose central processing unit (CPU), a graphics processing unit (GPU), an application specific integrated circuit (ASIC), or a programmable logic device. The programmable logic device is, for example, a simple programmable logic device (SPLD), a complex programmable logic device (CPLD), or a field programmable gate array (FPGA).

When the processor is, for example, a CPU, the processor reads and executes a program stored in storage circuitry to implement various functions. When the processor is, for example, an ASIC, a function corresponding to the program is directly incorporated as logic circuitry in circuitry of the processor, instead of storing the program in the storage circuitry. In this case, the processor implements various functions by hardware processing of reading and executing the program incorporated in the circuitry. Alternatively, the processor may implement various functions by combining software processing and hardware processing.

In the above exemplary embodiments, an example of the case where the single processor of the processing circuitry implements each function has been described, but the processing circuitry may be configured by combining a plurality of independent processors, and each processor may implement each function. In the case where the plurality of processors is provided, the storage circuitry that stores the program may be provided individually for each processor, or one storage circuitry may collectively store programs corresponding to the functions of all the processors.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A radio-frequency amplifying apparatus comprising:
an amplifier including an amplifying element configured to amplify a radio-frequency input signal, and a neutralizing capacitor configured to neutralize feedback capacitance of the amplifying element; and
control circuitry configured to change a drain voltage applied to the amplifying element according to a magnitude of the radio-frequency input signal and also apply the drain voltage to the neutralizing capacitor,
wherein the amplifier is configured to change capacitance of the neutralizing capacitor according to a magnitude of the drain voltage.

2. The radio-frequency amplifying apparatus according to claim 1, further comprising:
a fixed capacitance capacitor; and
a variable capacitance diode,
wherein the control circuitry is configured to apply the drain voltage to the variable capacitance diode.

3. The radio-frequency amplifying apparatus according to claim 2, wherein the amplifier is configured to divide the drain voltage and apply the divided drain voltage to the variable capacitance diode.

4. The radio-frequency amplifying apparatus according to claim 3, wherein the control circuitry is configured to change a voltage dividing ratio of a voltage applied to the variable capacitance diode according to the magnitude of the drain voltage.

5. The radio-frequency amplifying apparatus according to claim 4,
wherein the amplifier includes a plurality of resistors, and
wherein the control circuitry is configured to perform control of a switch for switching the plurality of resistors to change the voltage dividing ratio of the drain voltage.

6. The radio-frequency amplifying apparatus according to claim 1, wherein a circuit configuration of the amplifier is push-pull circuitry.

7. The radio-frequency amplifying apparatus according to claim 1, wherein the control circuitry is configured to acquire information regarding the radio-frequency input signal output from a sequence controller, and change the drain voltage based on the information regarding the radio-frequency input signal.

8. A magnetic resonance imaging apparatus comprising:
a sequence controller configured to output information regarding a radio-frequency input signal;
an amplifier including an amplifying element configured to amplify the radio-frequency input signal and a neutralizing capacitor configured to neutralize feedback capacitance of the amplifying element; and
control circuitry configured to change a drain voltage applied to the amplifying element according to a magnitude of the radio-frequency input signal and also apply the drain voltage to the neutralizing capacitor,
wherein the amplifier is configured to change capacitance of the neutralizing capacitor according to a magnitude of the drain voltage.
